(19) United States
(12) Patent Application Publication
(10) Pub. No.: US 2002/0144903 A1
(43) Pub. Date: Oct. 10, 2002

(54) Focused magnetron sputtering system

(75) Inventors: Steven Kim, Harrington Park, NJ (US); Minho Sohn, Glen Rock, NJ (US)

Correspondence Address: MORGAN LEWIS & BOCKIUS LLP, 1111 PENNSYLVANIA AVENUE NW, WASHINGTON, DC, 20004, US

(73) Assignee: PLASMION CORPORATION

(21) Appl. No.: 10/058,311

(22) Filed: Jan. 30, 2002

Related U.S. Application Data
(60) Provisional application No. 60/267,419, filed on Feb. 9, 2001.

(51) Int. Cl. C23C 14/34

(52) U.S. Cl. 204/298.18; 204/298.19; 204/298.17; 204/298.26

(57) ABSTRACT

A focused magnetron sputter system includes a processing chamber, a plurality of sputter sources arranged within the processing chamber, a substrate holder disposed above the plurality of sputter sources, a rotational shutter arranged between a substrate and the plurality of sputter sources for selectively forming a coating on the substrate, and a power supply connected to the substrate holder for supplying a substrate bias.

This application claims the benefit of a provision application, entitled “Focused Magnetron Sputtering System” which was filed Feb. 9, 2001, and assigned Provisional Application No. 60/267,419, which is hereby incorporated by reference.

### BACKGROUND OF THE INVENTION

1. Field of the Invention

The invention relates to a multi-layered coating system that uses multiple numbers of magnetron sources, and more particularly magnetron negative ion sputter sources. The invention is also related to an RF or pulsed DC power supply coupled to the substrate holder for supplying additional kinetic energy to the deposited ions.

2. Discussion of the Related Art

In general, fabrication of semiconductor and optical devices requires deposition of multiple materials using various deposition processes and techniques. One of the most common processes includes physical vapor deposition (PVD) using a sputtering system. In the sputtering system, a substrate is placed into a processing chamber, and an electric field is generated between a target and the substrate to form an electron cloud. Magnetic fields are produced to cause the electrons in the electron cloud to spiral and collide with reactive gas atoms, which are then ionized. Accordingly, the ionized reactive gas atoms are accelerated due to the magnetic field and strike the target, thereby removing atoms of the target. Then, the removed atoms of the target are deposited onto the substrate. After the process is completed, another substrate is loaded into the processing chamber and the process is repeated until a desired number of substrates are completely processed. Moreover, if additional different materials are to be deposited onto the substrate, then the substrate is transferred to other processing chambers for deposition of the additional different materials. However, such a sputtering system is problematic in that it cannot provide a high throughput of processed substrates. In addition, deposition of additional different materials requires significant amounts of additional processing time.

### SUMMARY OF THE INVENTION

Accordingly, the present invention is directed to a focused magnetron sputtering system that substantially obviates one or more of the problems due to limitations and disadvantages of the related art.

An object of the present invention is to provide a sputtering system having multiple sputter sources.

Another object of the present invention is to provide a sputtering system that allows for deposition of dense, uniform, and smooth multiple layer coatings while maintaining a high throughput.

Additional features and advantages of the invention will be set forth in the description which follows, and in part will be apparent from the description, or may learned by practice of the invention. The objectives and other advantages of the invention will be realized and attained by the structure particularly pointed out in the written description and claims hereof as well as the appended drawings.

To achieve these and other advantages and in accordance with the purpose of the present invention, as embodied and broadly described, a focused magnetron sputter system includes a processing chamber, a plurality of sputter sources arranged within the processing chamber, a substrate holder disposed above the plurality of sputter sources, a rotational shutter arranged between the substrate holder and the plurality of sputter sources, and a power supply connected to the substrate holder for supplying a substrate bias.

It is to be understood that both the foregoing general description and the following detail description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention and together with the description serve to explain the principles of the invention. In the drawings:

FIG. 1 illustrates an exemplary focused magnetron sputtering system according to the present invention;

FIG. 2 is a cross sectional view along I-I of FIG. 1, and illustrates an exemplary arrangement of sputter sources according to the present invention;

FIG. 3 is a cross sectional view along I-I of FIG. 1, and illustrates another exemplary arrangement of sputter sources according to the present invention;

FIG. 4 is a cross sectional view along I-I of FIG. 1, and illustrates another exemplary arrangement of sputter sources according to the present invention; and

FIG. 5 is a cross sectional view along I-I of FIG. 1, and illustrates another exemplary arrangement of sputter sources according to the present invention.

### DETAILED DESCRIPTION OF THE ILLUSTRATED EMBODIMENTS

Reference will now be made in detail to the illustrated embodiments of the present invention, examples of which are illustrated in the accompanying drawings.

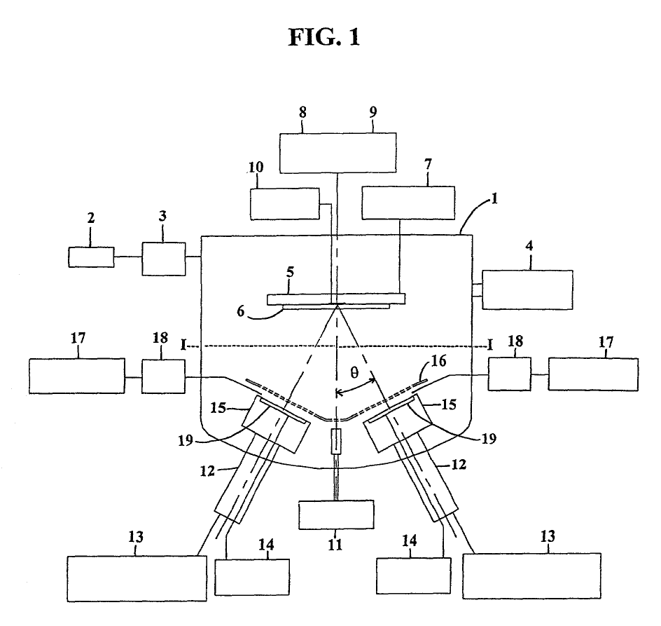

FIG. 1 illustrates an exemplary focused magnetron sputtering system according to the present invention. In FIG. 1, the focused magnetron sputtering system may include a processing chamber 1, a gas supply 2, a gas supply flow meter 3, a residual gas analyzer 4, and a vacuum pump (not shown). A substrate holder 5 included within the processing chamber 1, which holds a substrate 6, may be connected to a rotating motor (not shown). The substrate holder 5 may be electrically connected to a power supply 7 such as an RF or a straight or pulsed DC power supply, for example, to supply a bias to the substrate holder 5 and/or substrate 6, thereby generating plasma over the substrate 6 for sputter cleaning prior to deposition and for enhancement of reactive deposition. The substrate holder 5 may also be connected to process controlling devices to direct processing of the substrate 6. For example, temperature and/or rotation controllers 8 and 9 may be provided to control temperature and rotation of the substrate holder 5 and/or the substrate 6. In addition, the substrate holder 5 may be connected to monitoring devices 10 to monitor processing of the substrate 6. For example, a thickness monitoring device may be used to monitor a thickness of deposition material upon the substrate 6. Accordingly, the process chamber 1 may include a laser or any coherent light source 11 provided in opposition to the substrate 6 to provide the film thickness monitor 10 with coherent light for in-situ thickness monitoring.

The processing chamber 1 may include multiple negative ion sputter sources 12. The negative ion sputter sources 12 may each include at least one target material, for example, and may be geometrically disposed along wall portions of the processing chamber 1. Central axis of the negative ion sputter sources 12 may be arranged at an acute angle θ with respect to a central axis through a central portion of the surface of the substrate 6, thereby focusing generated sputtered neutral vapors and ionic vapors of coating materials from the negative ion sputter sources 12 onto the surface of the substrate 6, and increasing a throughput of the focused magnetron sputtering system. A distance between the substrate 6 and the negative ion sputter sources 12 is determined to optimize the deposition of materials.

Each of the negative ion sputter sources 12 may include a power supply source 13, a sputter enhancing source 14, and a magnetron 15 having a plurality of magnets (not shown) below a target 19 (e.g., sputter source). The power supply source 13 may include a straight or pulsed DC power supply, or RF power supply. Accordingly, since each of the negative ion sputter sources 12 generates sputtered materials in energetic negative ionic states and positive biasing of the substrate holder 5 by the power supply source 13 provides additional kinetic energy to the as-deposited ions, the focused magnetron sputtering system according to the present invention provides a highly dense, uniform, and smooth multi-layered optical coating. In addition, the sputter enhancing source 14 provides vaporized gas, such as cesium, to the negative ion sputter source 12 for enhancing a sputtering process. This is because a coating of low electron affinity elements such as cesium on a metal surface reduces the work function of the surface of the substrate. Thus, population of electrons at the surface is enhanced by the sputter enhancing source 14. The sputter enhancing source 14 is coupled to the plurality of sputter sources for providing cesium vapor in close proximity to surfaces of each target material. The magnets of adjacent ones of the negative ion sputter sources 12 may have the same or opposite polarities. Thus, the present invention improves optical properties in an optical filter for DWDM.

Disposed between the negative ion sputter sources 12 and the substrate holder 5 is a rotational shutter 16 that rotates via a drive motor (not shown), thereby exposing at least one of the negative ion sputter sources 12. During processing of the substrate 6, the rotational shutter 16 may allow different, or similar materials to be deposited on the substrate 6. During enhanced reactive sputtering and cleaning processes, a reactive gas supply 17 may be disposed between each of the negative ion sputter sources 12 and the rotational shutter 16 to supply a reactive gas such as oxygen and/or nitrogen, for example, via a flow meter 18.

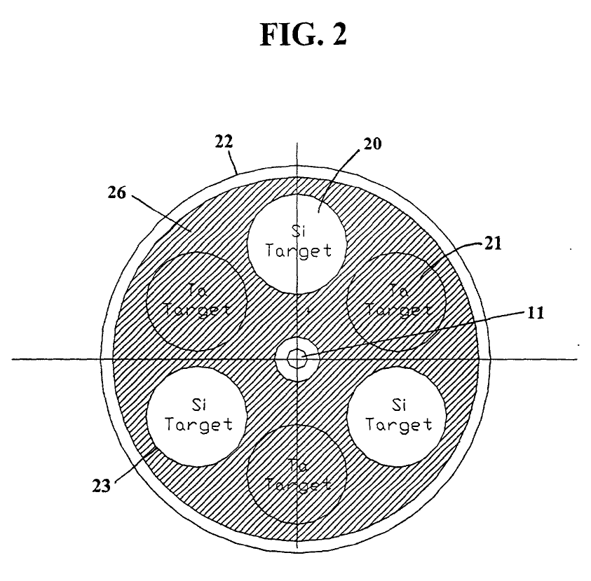

FIG. 2 is a cross sectional view along I-I of FIG. 1, and illustrates an exemplary arrangement of sputter sources according to the present invention. In FIG. 2, a first plurality of sputter sources 20 and a second plurality of sputter sources 21 may be geometrically arranged around a central axis about sidewall portions 22 of the processing chamber 1 (in FIG. 1). A total number of the first plurality of sputter sources 20 and a total number of the second plurality of sputter sources 21 may equal (as shown) or may be different (not shown) depending upon a multi-layered coating system. The first plurality of sputter sources 20 may include a first material or materials, such as silicon, and the second plurality of material sputter sources 21 may include a second material or materials, such as tantalum. In addition, a rotational shutter 26 is provided to overlie each of the first and second pluralities of sputter sources 20 and 21. The rotational shutter 26 may include a plurality of apertures 23 that correspond to diameters of the first and second pluralities of sputter sources 20 and 21. Accordingly, the rotational shutter 26 may allow at least one of the first and second pluralities of sputter sources 20 and 21 to be exposed to the processing chamber 1 (in FIG. 1). For example, during processing of the substrate 6 (in FIG. 1), the first plurality of sputter sources 20 may be exposed to deposit a first material or materials onto a surface of the substrate 6 (in FIG. 1). Then, the rotational shutter 26 may be rotated via a drive motor (not shown), thereby exposing the second plurality of sputter sources 21. During subsequent processing of the substrate 6 (in FIG. 1), the rotational shutter 26 may allow the second plurality of sputter sources 21 to deposit a second material or materials onto a surface of the substrate 6 (in FIG. 1).

The first and second pluralities of sputter sources 20 and 21, in combination with the rotational shutter 26, allow for forming a multi-layered coating on the substrate 6 (in FIG. 1). In addition, any number of combinations of first and second material layers may be formed on the substrate 6 (in FIG. 1), with each of the first and second material layers having relatively different or relatively similar thicknesses. Although first and second pluralities of sputter sources 20 and 21 are shown, any number of individual sputter sources may be implemented to deposit any corresponding number of materials. Moreover, although the first and second pluralities of sputter sources 20 and 21 are shown to have circular cross sections, any geometric cross section may be implemented. Furthermore, although the first and second pluralities of sputter sources 20 and 21 are shown to be disposed around the walls 22 of the processing chamber 1 (in FIG. 1) in a circular arrangement, other geometric arrangements may be implemented.

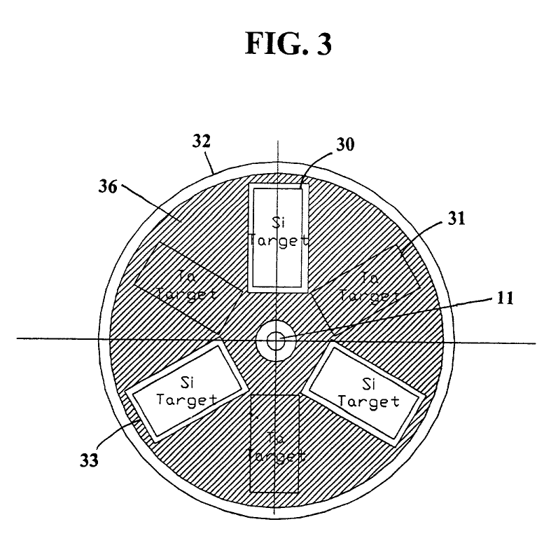

FIG. 3 is a cross sectional view along I-I of FIG. 1, and illustrates another exemplary arrangement of sputter sources according to the present invention. In FIG. 3, a first plurality of sputter sources 30 and a second plurality of sputter sources 31 may be geometrically arranged around a central axis about sidewall portions 32 of the processing chamber 1 (in FIG. 1). A total number of the first plurality of sputter sources 30 and a total number of the second plurality of sputter sources 31 may equal (as shown) or may be different (not shown) depending upon a multi-layered coating system. The first plurality of sputter sources 30 may include a first material or materials, such as silicon, and the second plurality of material sputter sources 31 may include a second material or materials, such as tantalum. In addition, a rotational shutter 36 may be provided to overlie each of the first and second pluralities of sputter sources 30 and 31. The rotational shutter 36 may include a plurality of apertures 33 that correspond to geometric surfaces of the first and second pluralities of sputter sources 30 and 31. Accordingly, the rotational shutter 36 may allow at least one of the first and second pluralities of sputter sources 30 and 31 to be exposed to the processing chamber 1 (in FIG. 1). For example, during processing of the substrate 6 (in FIG. 1), the first plurality of sputter sources 30 may be exposed to deposit a first material or materials onto a surface of the substrate 6 (in FIG. 6). Then, the rotational shutter 36 may be rotated via a drive motor (not shown), thereby exposing the second plurality of sputter sources 31. During subsequent processing of the substrate 6 (in FIG. 1), the rotational shutter 36 may allow the second plurality of sputter sources 31 to deposit a second material or materials onto a surface of the substrate 6 (in FIG. 1).

The first and second pluralities of sputter sources 30 and 31, in combination with the rotational shutter 36, allow for forming a multi-layered coating on the substrate 6 (in FIG. 1). In addition, any number of combinations of first and second material layers may be formed on the substrate 6 (in FIG. 1), with each of the first and second material layers having relatively different or relatively similar thicknesses. Although first and second pluralities of sputter sources 30 and 31 are shown, any number of individual sputter sources may be implemented to deposit any corresponding number of materials. Moreover, although the first and second pluralities of sputter sources 30 and 31 are shown to have rectangular cross sections, any geometric cross section may be implemented. Furthermore, although the first and second pluralities of sputter sources 30 and 31 are shown to be disposed around the walls 32 of the processing chamber 1 (in FIG. 1) in a circular arrangement, other geometric arrangements may be implemented.

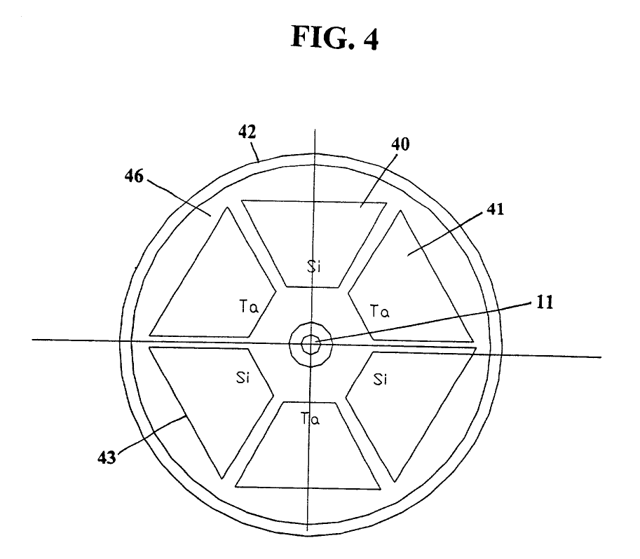

FIG. 4 is a cross sectional view along I-I of FIG. 1, and illustrates another exemplary arrangement of sputter sources according to the present invention. In FIG. 4, a first plurality of sputter sources 40 and a second plurality of sputter sources 41 may be geometrically arranged around a central axis about sidewall portions 42 of the processing chamber 1 (in FIG. 1). A total number of the first plurality of sputter sources 40 and a total number of the second plurality of sputter sources 41 may be equal (as shown) or may be different (not shown) depending upon a multi-layered coating system. The first plurality of sputter sources 40 may include a first material or materials, such as silicon, and the second plurality of material sputter sources 41 may include a second material or materials, such as tantalum. In addition, a rotational shutter 46 may be provided to overlie each of the first and second pluralities of sputter sources 40 and 41. The rotational shutter 46 may include a plurality of apertures 43 that correspond to geometric surfaces of the first and second pluralities of sputter sources 40 and 41. Accordingly, the rotational shutter 46 may allow at least one of the first and second pluralities of sputter sources 40 and 41 to be exposed to the processing chamber 1 (in FIG. 1). For example, during processing of the substrate 6 (in FIG. 1), the first plurality of sputter sources 40 may be exposed to deposit a first material or materials onto a surface of the substrate 6 (in FIG. 1). Accordingly, the rotational shutter 46 may be rotated via a drive motor (not shown), thereby exposing the second plurality of sputter sources 41. During subsequent processing of the substrate 6 (in FIG. 1), the rotational shutter 46 may allow the second plurality of sputter sources 41 to deposit a second material or materials onto a surface of the substrate 6 (in FIG. 1).

The first and second pluralities of sputter sources 40 and 41, in combination with the rotational shutter 46, allow for forming a multi-layered coating on the substrate 6 (in FIG. 1). In addition, any number of combinations of first and second material layers may be formed on the substrate 6 (in FIG. 1), with each of the first and second material layers having relatively different or relatively similar thicknesses. Although first and second pluralities of sputter sources 40 and 41 are shown, any number of individual sputter sources may be implemented to deposit any corresponding number of materials. Moreover, although the first and second pluralities of sputter sources 40 and 41 are shown to have trapezoidal cross sections, any geometric cross section may be implemented. Furthermore, although the first and second pluralities of sputter sources 40 and 41 are shown to be disposed around the walls 42 of the processing chamber 1 (in FIG. 1) in a circular arrangement, other geometric arrangements may be implemented.

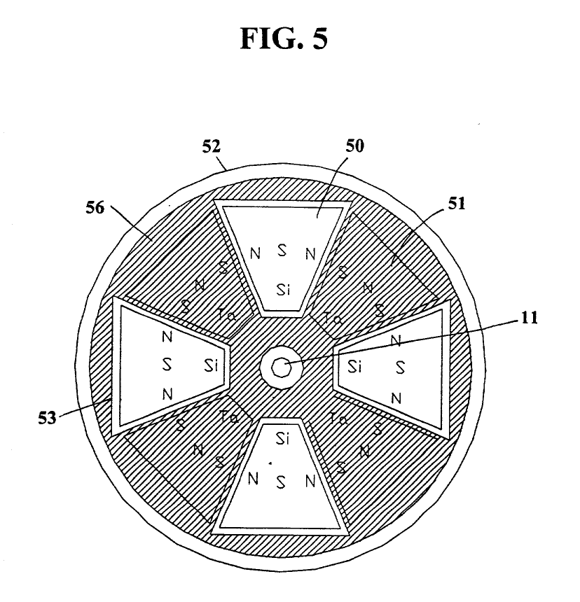

FIG. 5 is a cross sectional view along I-I of FIG. 1, and illustrates another exemplary arrangement of sputter sources according to the present invention. In FIG. 5, a first plurality of sputter sources 50 and a second plurality of sputter sources 51 may be geometrically arranged around a central axis about sidewall portions 52 of the processing chamber 1 (in FIG. 1). A total number of the first plurality of sputter sources 50 and a total number of the second plurality of sputter sources 51 may be equal (as shown) or may be different (not shown) depending upon a multi-layered coating system. The first plurality of sputter sources 50 may include a first material or materials, such as silicon, and the second plurality of material sputter sources 51 may include a second material or materials, such as tantalum. In addition, a rotational shutter 56 may be provided to overlie each of the first and second pluralities of sputter sources 50 and 51. The rotational shutter 56 may include a plurality of apertures 53 that correspond to geometric surfaces of the first and second pluralities of sputter sources 50 and 51. Accordingly, the rotational shutter 56 may allow at least one of the first and second pluralities of sputter sources 50 and 51 to be exposed to the processing chamber 1 (in FIG. 1). For example, during processing of the substrate 6 (in FIG. 1), the first plurality of sputter sources 50 may be exposed to deposit a first material or materials onto a surface of the substrate 6 (in FIG. 1). Accordingly, the rotational shutter 56 may be rotated via a drive motor (not shown), thereby exposing the second plurality of sputter sources 51. During subsequent processing of the substrate 6 (in FIG. 1), the rotational shutter 56 may allow the second plurality of sputter sources 51 to deposit a second material or materials onto a surface of the substrate 6 (in FIG. 1).

The first and second pluralities of sputter sources 50 and 51, in combination with the rotational shutter 56, allow for forming a multi-layered coating on the substrate 6 (in FIG. 6). In addition, any number of combinations of first and second material layers may be formed on the substrate 6 (in FIG. 1), with each of the first and second material layers having relatively different or relatively similar thicknesses. Although first and second pluralities of sputter sources 50 and 51 are shown, any number of individual sputter sources may be implemented to deposit any corresponding number of materials. Moreover, although the first and second pluralities of sputter sources 50 and 51 are shown to have trapezoidal cross sections, any geometric cross section may be implemented. Furthermore, although the first and second pluralities of sputter sources 50 and 51 are shown to be disposed around the walls 52 of the processing chamber 1 (in FIG. 1) in a circular arrangement, other geometric arrangements may be implemented. As shown in FIG. 5, a plurality of magnets may be located below the first and second pluralities of sputter sources 50 and 51 to confine electrons generated by the ionization of the argon gas to the surfaces of the sputter sources 50 and 51.

It will be apparent to those skilled in the art that various modifications and variations can be made in the focused magnetron sputtering system of the present invention without departing from the spirit or scope of the invention. Thus, it is intended that the present invention cover the modifications and variations of this invention provided they come within the scope of the appended claims and their equivalents.

What is claimed is:

1. A focused magnetron sputter system, comprising:
a processing chamber;
a plurality of sputter sources arranged within the processing chamber;
a substrate holder disposed above the plurality of sputter sources;
a rotational shutter arranged between a substrate and the plurality of sputter sources for selectively forming a coating on the substrate; and
a power supply connected to the substrate holder for supplying a substrate bias.

2. The system according to claim 1, wherein the processing chamber includes a vacuum pump, a gas flow meter, a residual gas analyzer, a laser light source, a monitor for coating thickness control, a substrate temperature controller, and a substrate rotation controller.

3. The system according to claim 1, wherein the plurality of sputter sources including a first plurality of sputter sources having a first target material and second plurality of sputter sources having a second target material.

4. The system according to claim 3, wherein the sputter sources are arranged at a portion of the processing chamber to focus negatively charged sputtered ions from the first and second target materials onto a substrate disposed at the substrate holder.

5. The system according to claim 3, wherein the first material includes silicon and the second material includes tantalum.

6. The system according to claim 1, further comprising a cesium vapor emitter coupled to the plurality of sputter sources for providing cesium vapor in close proximity to surfaces of each target material.

7. The system according to claim 1, wherein each of the plurality of sputter sources has a central axis disposed at an acute angle with respect to a central axis through a central portion of a substrate disposed on the substrate holder to focus negatively charged sputtered ions emitted from the plurality of sputter sources onto the substrate.

8. The system according to claim 1, further comprising at least one magnet below each sputter source.

9. The system according to claim 8, wherein the at least one magnet of adjacent sputter sources have similar polarities.

10. The system according to claim 8, wherein the at least one magnet of adjacent sputter sources have opposite polarities.

11. The system according to claim 1, wherein the rotational shutter includes a plurality of apertures, each aperture has a geometry corresponding to geometries of the plurality of sputter sources.

12. The system according to claim 1, wherein the power supply provides RF energy to the substrate.

13. The system according to claim 1, wherein the power supply provides one of pulsed and straight direct currents to the substrate.

14. The system according to claim 1, wherein the direct currents are positively biased.

15. The system according to claim 1, wherein the power supply generates a plasma over the substrate.

16. The system according to claim 15, wherein the plasma generated over the substrate provides sputter cleaning prior to deposition.

17. The system according to claim 15, wherein the plasma generated over the substrate provides enhanced reactive deposition.

18. The system according to claim 15, wherein the plasma includes one of an oxygen and nitrogen plasma to enhance the oxidation and nitridation at the substrate during deposition.
